(19) United States
(12) Patent Application Publication
(10) Pub. No.: US 2026/0057919 A1
(43) Pub. Date: Feb. 26, 2026

(54) MEMORY DEVICE AND OPERATING METHOD OF THE SAME

(71) Applicant: Samsung Electronics Co., Ltd., Suwon-si (KR)

(72) Inventor: Hwayeong LEE, Suwon-si (KR)

(73) Assignee: Samsung Electronics Co., Ltd., Suwon-si (KR)

(21) Appl. No.: 19/297,649

(22) Filed: Aug. 12, 2025

(30) Foreign Application Priority Data
Aug. 21, 2024 (KR) 10-2024-0112346

(51) Int. Cl. G11C 11/00; H10B 12/00; H10B 51/30

(52) U.S. Cl. CPC G11C 11/005; H10B 12/315; H10B 51/30

(57) ABSTRACT

A memory device includes a bit line extending in a first horizontal direction, a vertical channel layer extending in a vertical direction on the bit line, a first dielectric layer and a second dielectric layer both extending in the vertical direction with the vertical channel layer therebetween, a pair of word lines facing each other with the vertical channel layer, the first dielectric layer, and the second dielectric layer therebetween, a plate line positioned on the vertical channel layer, the first dielectric layer, and the second dielectric layer, and a capacitor structure arranged on the plate line, and at least one of the first or second dielectric layers includes a ferroelectric.

### CROSS-REFERENCE TO RELATED APPLICATION

This application claims priority under 35 U.S. C. § 119 to Korean Patent Application No. 10-2024-0112346, filed on Aug. 21, 2024, in the Korean Intellectual Property Office, the disclosure of which is incorporated by reference herein in its entirety.

### BACKGROUND

Example embodiments of the inventive concepts relate to a memory device including ferroelectric and an operating method of the same.

As electronic products become faster and consume lesser power, it is beneficial to improve the programming/sensing operations and lower operating voltages of memory devices in the electronic products. Ferroelectric materials that maintain spontaneous polarization by aligning internal electric dipole moments even in an absence of an external electric field are being studied. It may be advantageous to use non-volatile memory using a ferroelectric in electronic products.

### SUMMARY

Example embodiments of the inventive concepts relate to a memory device that may be selectively operated as volatile memory or non-volatile memory and have a relatively higher integration and improved electrical reliability, and an operating method of the same.

The memory device and operating method, according to example embodiments according to the of the inventive concepts, are not limited to example embodiments disclosed herein, and may be embodied in many other forms without departing from the spirit or scope of the present disclosure.

According to some example embodiments of the inventive concepts, there is provided a memory device including a bit line extending in a first horizontal direction, a vertical channel layer extending in a vertical direction on the bit line, a first dielectric layer and a second dielectric layer both extending in the vertical direction with the vertical channel layer therebetween, a pair of word lines facing each other with the vertical channel layer, the first dielectric layer, and the second dielectric layer therebetween, a plate line on the vertical channel layer, the first dielectric layer, and the second dielectric layer, and a capacitor structure on the plate line. At least one of the first dielectric layer or the second dielectric layers comprises a ferroelectric.

According to some example embodiments of the inventive concepts, there is provided a memory device including a lower memory structure and an upper memory structure on the lower memory structure. The lower memory structure includes a first bit line extending in a first horizontal direction, a first vertical channel layer extending in a vertical direction on the first bit line, a first dielectric layer and a second dielectric layer both extending in the vertical direction with the first vertical channel layer therebetween, a first word line and a second word line facing each other with the first vertical channel layer, the first dielectric layer, and the second dielectric layer therebetween, a first plate line on the first vertical channel layer, the first dielectric layer, and the second dielectric layer, and a first capacitor structure on the first plate line. The upper memory structure includes a second bit line extending in the first horizontal direction, a second vertical channel layer extending in the vertical direction on the second bit line, a third dielectric layer and a fourth dielectric layer both extending in the vertical direction with the second vertical channel layer therebetween, third and fourth word lines facing each other with the second vertical channel layer, the third dielectric layer, and the fourth dielectric layer therebetween, a second plate line on the second vertical channel layer, the third dielectric layer, and the fourth dielectric layer, and a second capacitor structure on the second plate line. At least one of the first dielectric layer or the second dielectric layer includes a ferroelectric, and at least one of the third dielectric layer or the fourth dielectric layer includes a ferroelectric.

According to some example embodiments of the inventive concepts, there is provided a memory device including a first memory structure and a second memory structure side by side in a first horizontal direction. The first memory structure includes a first bit line extending in the first horizontal direction, a first vertical channel layer extending in a vertical direction on the first bit line, a pair of first dielectric layers extending in the vertical direction with the first vertical channel layer therebetween, a pair of first word lines facing each other with the first vertical channel layer and the pair of first dielectric layers therebetween, and a capacitor structure on the first vertical channel layer and the pair of first dielectric layers. The second memory structure includes a second bit line extending in the first horizontal direction, a second vertical channel layer extending in the vertical direction on the second bit line, a pair of second dielectric layers extending in the vertical direction with the second vertical channel layer therebetween, a pair of second word lines facing each other with the second vertical channel layer and the pair of second dielectric layers therebetween, and a plate line positioned on the second vertical channel layer and the pair of second dielectric layers. At least one of the pair of first dielectric layers or the pair of second dielectric layers includes a ferroelectric.

### BRIEF DESCRIPTION OF THE DRAWINGS

These and other aspects, features, and advantages of some example embodiments will be more clearly understood from the following detailed description, taken in conjunction with the accompanying drawings.

FIG. 1 is a block diagram illustrating a memory device, according to some example embodiments.

FIG. 2 is a cross-sectional view of a memory device, according to some example embodiments.

FIGS. 3, 4, 5, and 6 illustrate an operation of volatile memory in the memory device illustrated in FIG. 2, according to some example embodiments.

FIGS. 7, 8, 9, and 10 illustrate an operation of non-volatile memory in the memory device illustrated in FIG. 2.

FIG. 11 is a cross-sectional view illustrating a memory device, according to some example embodiments.

FIG. 12 is a cross-sectional view illustrating a memory device, according to some example embodiments.

FIGS. 13 and 14 illustrate an operation of volatile memory in the memory device illustrated in FIG. 12.

FIGS. 15 and 16 illustrate an operation of non-volatile memory in the memory device illustrated in FIG. 12.

FIGS. 17 and 18 are cross-sectional views illustrating a memory device, according to some example embodiments.

FIG. 19 is a block diagram illustrating a configuration of a system including a memory device, according to some example embodiments.

### DETAILED DESCRIPTION OF THE EMBODIMENTS

Hereinafter, some example embodiments of the inventive concepts will be described in detail with reference to the accompanying drawings.

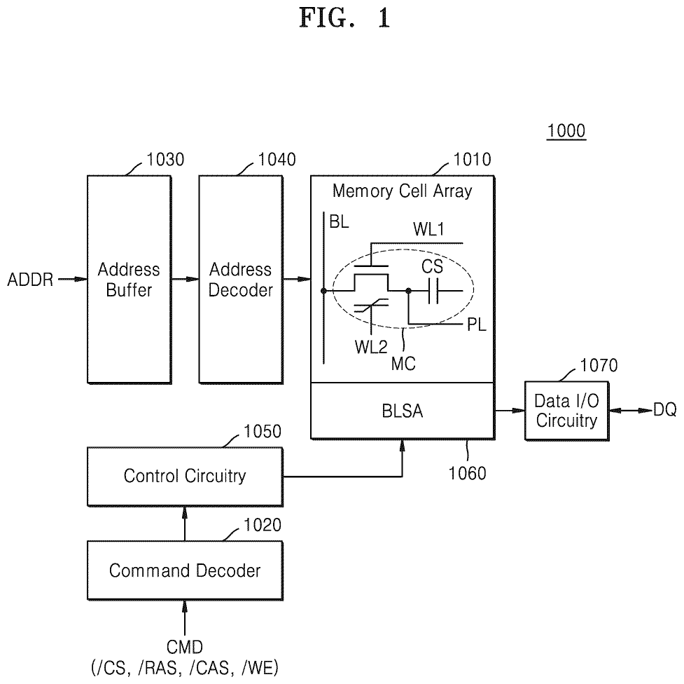

FIG. 1 is a block diagram illustrating a memory device 1000, according to some example embodiments.

Referring to FIG. 1, the memory device 1000 according to some example embodiments may include a memory cell array 1010, a command decoder 1020, an address buffer 1030, an address decoder 1040, a control circuitry 1050, a sense amplifier (or a bit line sense amplifier (BLSA)) 1060, and/or a data input/output circuitry 1070.

The memory device 1000 may include dynamic random access memory (DRAM) using a cell capacitor CS as a data storage unit and a ferroelectric field-effect transistor (FeFET) detecting a cell voltage stored in a memory cell MC as data.

The memory device 1000 may input/output data DQ in response to a command CMD and an address ADDR received from an external device (for example, a central processing unit (CPU) or a memory controller).

The memory cell array 1010 may include a plurality of memory cells MC. The memory cell array 1010 may include a first word line WL1 and a second word line WL2, a bit line BL, and a plate line PL. Each of the first word line WL1, the second word line WL2, the bit line BL, and the plate line PL are connected to each memory cell MC of the plurality of memory cells MC in the memory cell array 1010.

Each of the plurality of memory cells MC may include both volatile memory and non-volatile memory. Operations of the volatile memory and the non-volatile memory may be selectively performed as needed.

A gate end (or terminal) of the volatile memory may be connected to the first word line WL1 of the memory cell array 1010. A first end (or terminal) of the volatile memory may be connected to the bit line BL of the memory cell array 1010. A second end (or terminal) of the volatile memory may be connected to a first end (or terminal) of the cell capacitor CS. In addition, the first end (or terminal) of the cell capacitor CS may be connected to the plate line PL of the memory cell array 1010. The volatile memory may store charges corresponding to data in the cell capacitor CS.

A gate end (or terminal) of the non-volatile memory may be connected to the second word line WL2 of the memory cell array 1010. A first end (or terminal) of the non-volatile memory may be connected to the bit line BL of the memory cell array 1010. A second end (or terminal) of the non-volatile memory may be connected to the plate line PL of the memory cell array 1010. The non-volatile memory may store a cell voltage having a magnitude specifying or otherwise representing data in a ferroelectric layer.

The command decoder 1020 may determine the input command CMD with reference to a chip selection signal /CS, a row address strobe signal /RAS, a column address strobe signal /CAS, and/or a write enable signal /WE applied from an external device. The command decoder 1020 may generate a control signal corresponding to the command CMD. The command CMD may include an active command, a read command, a write command, and/or a precharge command.

The address buffer 1030 receives the address ADDR applied from the external device. The address ADDR includes a word line address addressing the first and second word lines WL1 and WL2 connected to the memory cell array 1010, a bit line address addressing the bit line BL connected to the memory cell array 1010, and a plate address addressing the plate line PL connected to the memory cell array 1010. The address buffer 1030 may transmit the word line address, the bit line address, and the plate line address to the address decoder 1040.

The address decoder 1040 may include a word line decoder, a bit line decoder, and a plate line decoder selecting the first and second word lines WL1 and WL2, the bit line BL, and the plate line PL of the memory cell MC to be accessed in response to the received address ADDR.

The word line decoder may decode the word line address to activate the first and/or second word lines WL1 and WL2 of the memory cell MC corresponding to the word line address. The bit line decoder may decode the bit line address to provide a bit line selection signal for selecting the bit line BL of the memory cell MC corresponding to the bit line address. The plate line decoder may decode the plate line address to provide a plate line selection signal for selecting the plate line PL of the memory cell MC corresponding to the plate line address.

The control circuitry 1050 may control the sense amplifier 1060 according to control of the command decoder 1020. The control circuitry 1050 may control an operation of sensing the cell voltage of the memory cell MC of the sense amplifier 1060. The control circuitry 1050 may control the sense amplifier 1060 to perform a pre-charging operation, a charge sharing operation, and/or a sensing operation.

The sense amplifier (or bit line sense amplifier (BLSA)) 1060 may sense the charges stored in the memory cell MC as data. In addition, the sense amplifier 1060 may transmit the sensed data to the data input/output circuitry 1070 so that the sensed data is output to the outside of the memory device 1000 through a data DQ pad.

The data input/output circuitry 1070 may receive the data DQ to be written in the memory cell MC from the outside (e.g., from an external source) to transmit the data DQ to the memory cell array 1010. The data input/output circuitry 1070 may output bit data sensed by the sense amplifier 1060 as read data to the outside through the data DQ pad.

The memory device 1000 according to some example embodiments of the inventive concepts, in which at least one of a pair of gate dielectric layers includes a ferroelectric, constitutes hybrid memory that may selectively operate as volatile memory or non-volatile memory, and may have a relatively higher integration and/or electrical reliability.

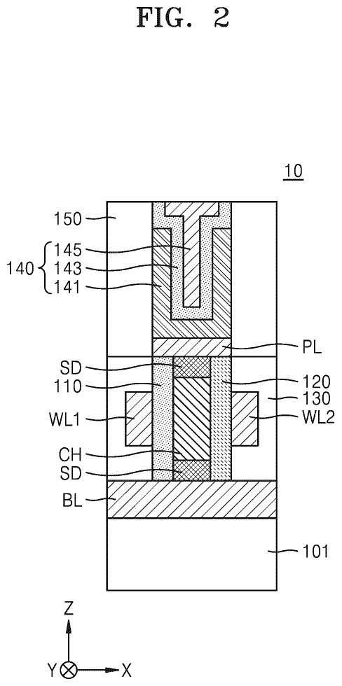

FIG. 2 is a cross-sectional view illustrating a memory device 10 according to some example embodiments.

Referring to FIG. 2, the memory device 10 according to some example embodiments may include a memory cell having a vertical channel transistor (VCT) structure.

The memory device 10 (e.g., hybrid memory device 10) according to some example embodiments of the inventive concepts may include a substrate 101, a bit line BL, a vertical channel layer CH, a first dielectric layer 110, a second dielectric layer 120, a first word line WL1, a second word line WL2, a plate line PL, and a capacitor structure 140.

The substrate 101 may be a wafer including silicon (Si). In some example embodiments, the substrate 101 may be a wafer including a semiconductor element such as germanium (Ge), or a compound semiconductor such as silicon carbide (SiC), gallium arsenide (GaAs), indium arsenide (InAs), or indium phosphide (InP). Meanwhile, the substrate 101 may have a silicon-on-insulator (SOI) structure. The substrate 101 may include a conductive region, for example, an impurity-doped well or an impurity-doped structure.

The bit line BL may extend in a first horizontal direction (X direction) on the substrate 101. The bit line BL may include a plurality of bit lines BL which extend in the first horizontal direction (X direction) and are apart from one another in a second horizontal direction (Y direction) intersecting the first horizontal direction (X direction). The bit line BL may include a conductive line. In some example embodiments, the bit line BL may include conductive metal nitride (for example, titanium nitride or tantalum nitride) or a metal (for example, tungsten (W), titanium (Ti) or tantalum (Ta)). Alternatively, the bit line BL may include metal silicide such as titanium silicide, cobalt silicide, or nickel silicide. Alternatively, the bit line BL may include doped polysilicon.

The vertical channel layer CH may extend in a vertical direction (Z direction) on the bit line BL. Here, the vertical channel layer CH may include a single crystal semiconductor material layer formed by a selective epitaxial growth method. In some example embodiments, the vertical channel layer CH may include single crystal silicon (Si). In some example embodiments, the vertical channel layer CH may include doped silicon (Si) with a predetermined or desired conductivity type and a predetermined or desired doping concentration by controlling a dopant and/or a doping concentration in the selective epitaxial growth process.

The vertical channel layer CH may include a source/drain region SD adjacent (or proximate) to the bit line BL at one (or lower) end thereof and a source/drain region SD adjacent (or proximate) to the plate line PL at the other (or upper) opposite end thereof. The vertical channel layer CH may refer to a channel region between the source/drain regions SD at opposite ends thereof. The channel region may be controlled by each of the first and second word lines WL during operation of the memory device 10.

The first dielectric layer 110 and the second dielectric layer 120 may be arranged on both sidewalls of the vertical channel layer CH. Each of the first dielectric layer 110 and the second dielectric layer 120 may extend in the second horizontal direction (Y direction). In addition, each of the first dielectric layer 110 and the second dielectric layer 120 may extend from the lowermost end of the lower source/drain region SD to the uppermost end of the upper source/drain region SD in the vertical direction (Z direction). A bottom surface of each of the first dielectric layer 110 and the second dielectric layer 120 may contact a top surface of the bit line BL, and a top surface of each of the first dielectric layer 110 and the second dielectric layer 120 may contact a bottom surface of the plate line PL.

In the memory device 10 according to some example embodiments of the inventive concepts, at least one of the first dielectric layer 110 and the second dielectric layer 120 may include a ferroelectric. The ferroelectric may refer to a material with ferroelectricity maintaining spontaneous polarization. In some example embodiments, the ferroelectric may be a single thin film structure, a stacked thin film structure, or a composite film structure having a laminate structure.

For example, the ferroelectric may include at least one of hafnium oxide, hafnium zirconium oxide, zirconium oxide, barium strontium titanium oxide, barium titanium oxide, and lead zirconium titanium oxide. Here, hafnium zirconium oxide may be a material in which hafnium oxide is doped with zirconium (Zr), or may be a compound of hafnium (Hf), zirconium (Zr), and oxygen (O).

The ferroelectric may further include a doping element in the material described above. The doping element may be or include at least one of, for example, aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn).

In some example embodiments, the second dielectric layer 120 may include a ferroelectric, and the first dielectric layer 110 may not include a ferroelectric. In this case, the first dielectric layer 110 may include, for example, silicon oxide, silicon nitride, silicon oxynitride, silicon oxycarbonitride, a high-k dielectric film having a higher dielectric constant than a silicon oxide film, or a combination thereof. Alternatively, in some example embodiments, the first dielectric layer 110 may include a ferroelectric, and the second dielectric layer 120 may not include a ferroelectric. In this case, the second dielectric layer 120 may include, for example, silicon oxide, silicon nitride, silicon oxynitride, silicon oxycarbonitride, a high-k dielectric film having a higher dielectric constant than a silicon oxide film, or a combination thereof.

The first and second word lines WL1 and WL2 may face each other with the vertical channel layer CH and the first and second dielectric layers 110 and 120 therebetween. Each of the first and second word lines WL1 and WL2 may have a vertical length less than that of the vertical channel layer CH in the vertical direction (Z direction). The first and second word lines WL1 and WL2 may be positioned such that a level of the uppermost surface of the vertical channel layer CH may be higher than a level of the uppermost surface of each of the first and second word lines WL1 and WL2, and a level of the lowermost surface of the vertical channel layer CH may be lower than a level of the lowermost surface of each of the first and second word lines WL1 and WL2. The first and second word lines WL1 and WL2 may include, for example, doped polysilicon, a metal, conductive metal nitride, conductive metal silicide, conductive metal oxide, or a combination thereof.

A lower insulating layer 130 may surround the first and second dielectric layers 110 and 120 and the first and second word lines WL1 and WL2. The first and second word lines WL1 and WL2 may be electrically isolated from other neighboring word lines by the lower insulating layer 130. The lower insulating layer 130 may include, for example, silicon oxide, silicon oxynitride, or silicon nitride.

The plate line PL may be positioned on the vertical channel layer CH and the first and second dielectric layers 110 and 120. The plate line PL may directly contact and be electrically connected to a lower electrode 141 of a capacitor structure 140. The plate line PL may directly contact and be electrically connected to the upper source/drain region SD. The plate line PL may include, for example, a metal, conductive metal nitride, conductive metal silicide, conductive metal oxide, or a combination thereof.

The capacitor structure 140 may be arranged on the plate line PL. The capacitor structure 140 may corresponding to the cell capacitor CS (refer to FIG. 1). The capacitor structure 140 may be electrically connected to the vertical channel layer CH. The capacitor structure 140 may be arranged in a matrix in the first horizontal direction (X direction) and the second horizontal direction (Y direction) intersecting the first horizontal direction (X direction). The capacitor structure 140 may completely or partially overlap the plate line PL. In other words, the capacitor structure 140 may completely or partially contact a top surface of the plate line PL.

In some example embodiments, the capacitor structure 140 may include the lower electrode 141 and an upper electrode 145, and a capacitor dielectric layer 143 therebetween. In this configuration, the lower electrode 141 may directly contact the plate line PL. When viewed in a plan view, the lower electrode 141 may have various shapes such as circular, oval, rectangular, square, diamond, and hexagonal shapes.

An upper insulating layer 150 may surround the plate line PL and the capacitor structure 140. The capacitor structure 140 may be electrically isolated from other neighboring capacitor structures by the upper insulating layer 150. The upper insulating layer 150 may include, for example, silicon oxide, silicon oxynitride, or silicon nitride.

The memory device 10 according to some example embodiments of the inventive concepts may selectively operate as volatile memory or non-volatile memory by using or based on a difference in voltages applied to the first and second word lines WL1 and WL2. The characteristics of the memory device 10 operating as volatile memory may be referred to as a ‘DRAM mode’, and the characteristics of the memory device 10 operating as non-volatile memory may be referred to as an ‘FeFET mode’.

The memory device 10 according to some example embodiments of the inventive concepts may store data by using the capacitor structure 140 in the DRAM mode and may store data by using polarization characteristics of any one of the first and second dielectric layers 110 and 120 in the FeFET mode.

For example, a magnitude of the voltage applied to the first word line WL1 may be set to be in a range that may not cause the polarization characteristics of the first dielectric layer 110, or a material constituting the first dielectric layer 110 may include an insulating material that may not have polarization characteristics. In this case, the memory device 10 may operate in the DRAM mode by using the bit line BL, the vertical channel layer CH, the first dielectric layer 110, the first word line WL1, the plate line PL, and the capacitor structure 140.

For example, a material constituting the second dielectric layer 120 may include a ferroelectric having polarization characteristics, and a magnitude of the voltage applied to the second word line WL2 may be set to be in a range that causes the polarization characteristics of the second dielectric layer 120. In this case, the memory device 10 may operate in the FeFET mode by using the bit line BL, the vertical channel layer CH, the second dielectric layer 120, the second word line WL2, and the plate line PL.

Operating principles of a programming operation (or a write operation, hereinafter collectively referred to as a programming operation) and a sensing operation (or a read operation, hereinafter referred to as a sensing operation) of the memory device 10 according to some example embodiments of the inventive concepts in each of the DRAM mode and the FeFET mode will be described below.

The memory device 10, according to some example embodiments of the inventive concepts, in which at least one of a pair of gate dielectric layers (for example, the first and second dielectric layers) includes a ferroelectric, may constitute hybrid memory that may selectively operate as volatile memory (e.g., the DRAM mode) or non-volatile memory (e.g., the FeFET mode) and may have a relatively higher integration and electrical reliability.

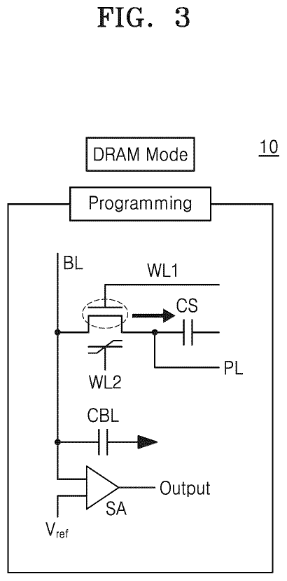

FIGS. 3 to 6 are diagrams illustrating an operation of volatile memory in the memory device 10 illustrated in FIG. 2, according to some example embodiments.

FIGS. 3 to 6 describe operating principles of a programming operation and a sensing operation when the memory device 10 according to some example embodiments of the inventive concepts operates as volatile memory (e.g., a DRAM mode).

In order for the memory device 10 to operate in the DRAM mode, as described above, the magnitude of the voltage applied to the first word line WL1 may be set to be in a range that may not cause the polarization characteristics of the first dielectric layer (dotted circle), or the material constituting the first dielectric layer (dotted circle) may include an insulating material that may not have polarization characteristics.

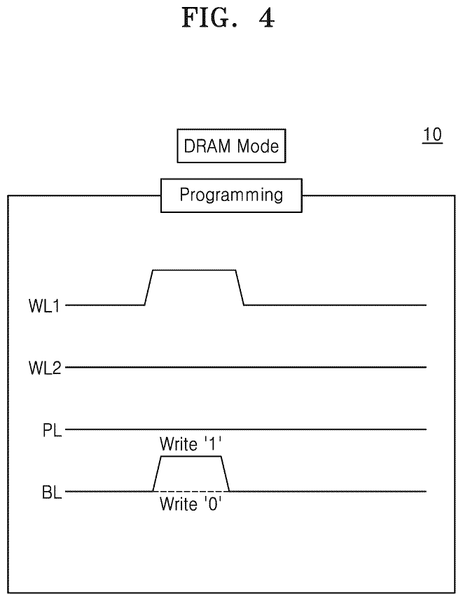

When the memory device 10 according to some example embodiments of the inventive concepts performs a programming operation (refer to FIGS. 3 and 4) in the DRAM mode, a voltage may be applied to the first word line WL1 and the bit line BL to write data (for example, ‘0’ or ‘1’) in the cell capacitor CS.

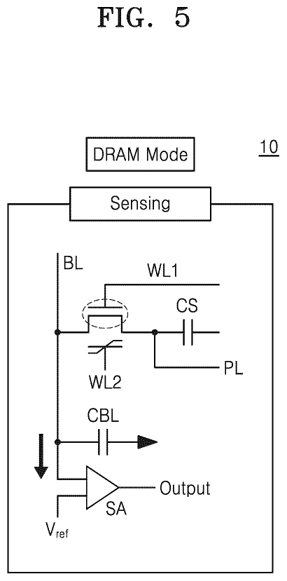

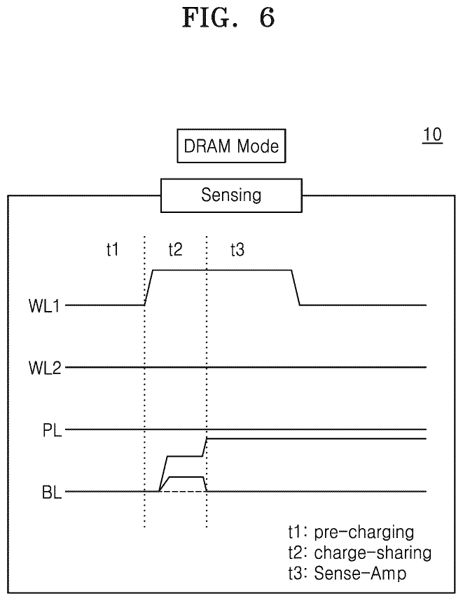

In addition, when the memory device 10 according to some example embodiments of the inventive concepts performs a sensing operation (refer to FIGS. 5 and 6) in the DRAM mode, the cell capacitor CS and a parasitic capacitor CBL perform a charge sharing operation, and data (for example, ‘0’ or ‘1’) may be read through a change in voltage level of the bit line BL. Here, the control circuitry 1050 (refer to FIG. 1) may control a sense amplifier SA to sequentially perform a pre-charging operation t1, a charge sharing operation t2, and a sense amplifying operation t3.

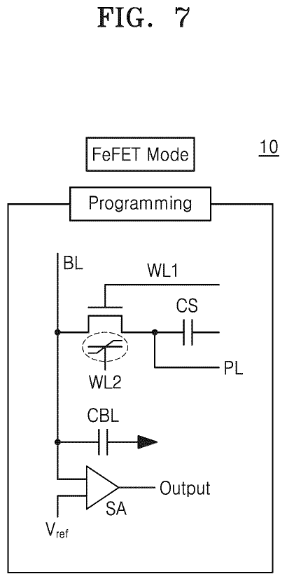

FIGS. 7 to 10 are diagrams illustrating an operation of non-volatile memory in the memory device 10 illustrated in FIG. 2, according to some example embodiments.

FIGS. 7 to 10 describe operating principles of a programming operation and a sensing operation when the memory device 10 according to some example embodiments of the inventive concepts operates as non-volatile memory (e.g., an FeFET mode).

In order for the memory device 10 to operate in the FeFET mode, as described above, the material constituting the second dielectric layer (dotted circle) may include a ferroelectric having polarization characteristics and the magnitude of the voltage applied to the second word line WL2 may be set to be in a range that causes the polarization characteristics of the second dielectric layer (dotted circle).

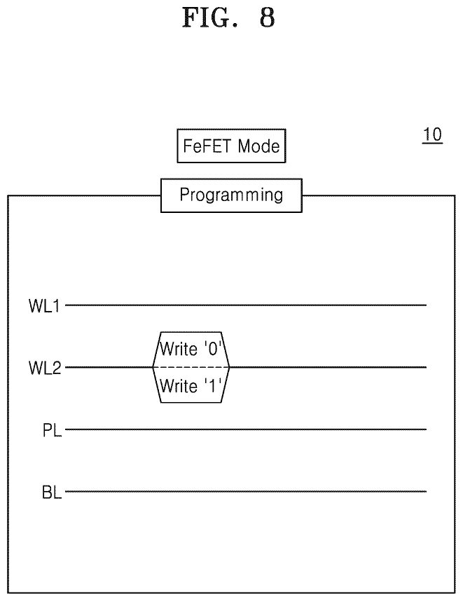

When the memory device 10 according to some example embodiments of the inventive concepts performs a programming operation (refer to FIGS. 7 and 8) in the FeFET mode, by applying a voltage to the second word line WL2, polarization may be induced to store a cell voltage having a magnitude specifying data in the second dielectric layer (dotted circle) so that data (for example, ‘0’ or ‘1’) may be written.

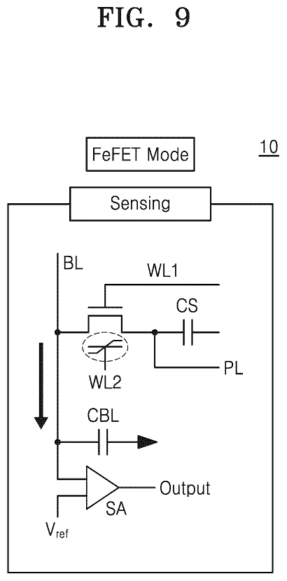

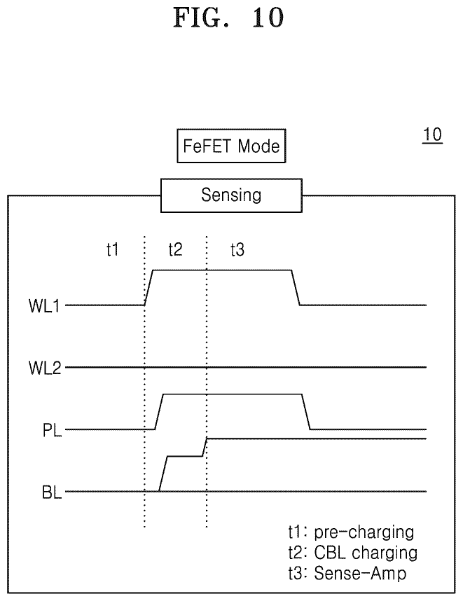

In addition, when the memory device 10 according to some example embodiments of the inventive concepts performs a sensing operation (refer to FIGS. 9 and 10) in the FeFET mode, by applying a voltage to the first word line WL1 and the plate line PL, according to whether the second dielectric layer (dotted circle) is polarized, data (for example, ‘0’ or ‘1’) may be read through whether the parasitic capacitor CBL is charged. Here, the control circuitry 1050 (refer to FIG. 1) may control a sense amplifier SA to sequentially perform a pre-charging operation t1, a parasitic capacitor charging operation t2, and a sense amplifying operation t3.

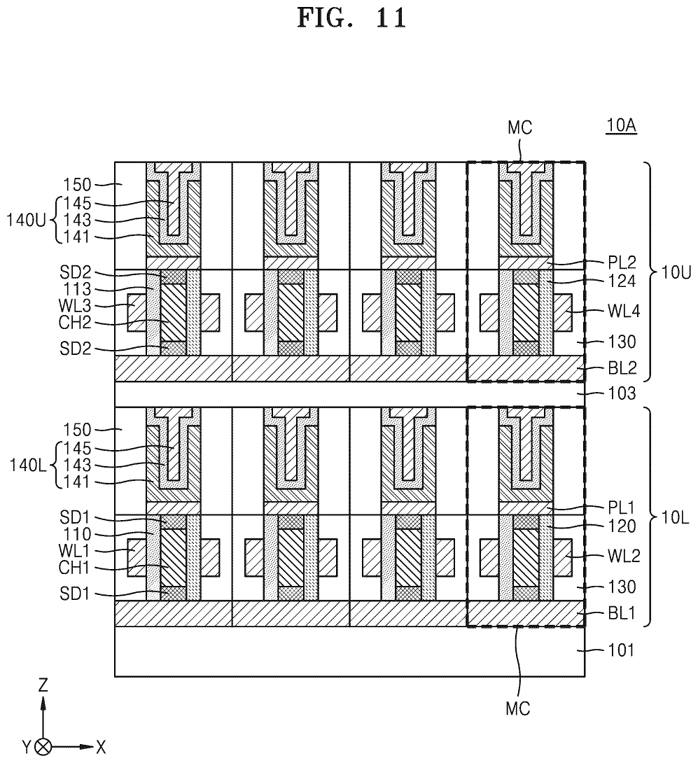

FIG. 11 is a cross-sectional view illustrating a memory device 10A, according to some example embodiments.

The memory device 10A may be same as or similar in some respects to the memory device 10 of FIG. 2, and therefore may be best understood with reference thereto where like numerals indicate like elements not described again in detail.

Referring to FIG. 11, the memory device 10A according to some example embodiments of the inventive concepts may include a plurality of memory cells MC each having a vertical channel transistor structure in a stacked structure.

The memory device 10A according to some example embodiments of the inventive concepts may include a lower memory structure 10L and an upper memory structure 10U on the lower memory structure 10L.

The lower memory structure 10L may include a plurality of memory cells MC arranged side by side on a substrate 101 in the first horizontal direction (X direction).

Each of the plurality of memory cells MC of the lower memory structure 10L may include a first bit line BL1 extending in the first horizontal direction (X direction), a first vertical channel layer CH1 extending in the vertical direction (Z direction) on the first bit line BL1, a first source/drain region SD1 at vertically opposite ends of the first vertical channel layer CH1, a first dielectric layer 110 and a second dielectric layer 120 both extending in the vertical direction (Z direction) with the first vertical channel layer CH1 therebetween, a first word line WL1 and a second word line WL2 facing each other with the first vertical channel layer CH1 and the first and second dielectric layers 110 and 120 therebetween, a first plate line PL1 positioned on the first vertical channel layer CH1 and the first and second dielectric layers 110 and 120, and a first capacitor structure 140L arranged on the first plate line PL1.

In some example embodiments, an interlayer insulating layer 103 may be arranged between the lower memory structure 10L and the upper memory structure 10U.

The upper memory structure 10U may include a plurality of memory cells MC arranged side by side on the interlayer insulating layer 103 in the first horizontal direction (X direction).

Each of the plurality of memory cells MC of the upper memory structure 10U may include a second bit line BL2 extending in the first horizontal direction (X direction), a second vertical channel layer CH2 extending in the vertical direction (Z direction) on the second bit line BL2, a second source/drain region SD2 at both ends of the second vertical channel layer CH2, a third dielectric layer 113 and a fourth dielectric layer 124 both extending in the vertical direction (Z direction) with the second vertical channel layer CH2 therebetween, third and fourth word lines WL3 and WL4 facing each other with the second vertical channel layer CH2 and the third and fourth dielectric layers 113 and 124 therebetween, a second plate line PL2 positioned on the second vertical channel layer CH2 and the third and fourth dielectric layers 113 and 124, and a second capacitor structure 140U arranged on the second plate line PL2.

In the memory device 10A according to some example embodiments of the inventive concepts, at least one of the first dielectric layer 110 and the second dielectric layer 120 may include a ferroelectric. In addition or alternatively, at least one of the third dielectric layer 113 and the fourth dielectric layer 124 may include a ferroelectric.

In the memory device 10A according to some example embodiments of the inventive concepts, a plurality of memory cells MC included in the lower memory structure 10L may be substantially the same as or similar to a plurality of memory cells MC included in the upper memory structure 10U. The operating characteristics of the plurality of memory cells MC are substantially the same as or similar to those of the memory device 10 described above and a detailed description thereof is omitted for the sake of brevity.

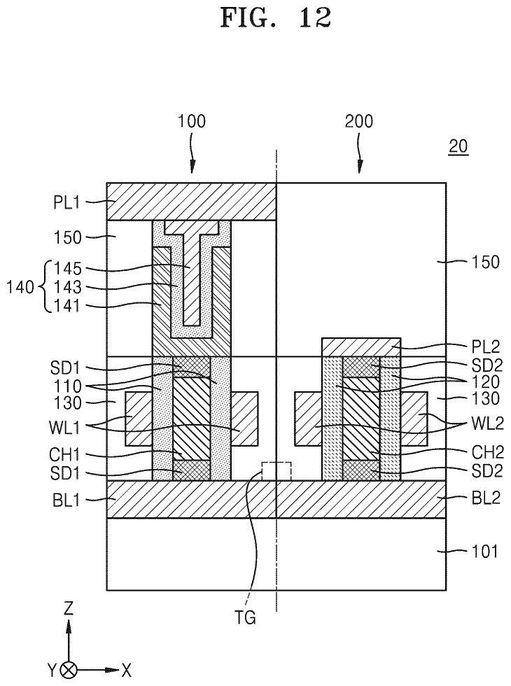

FIG. 12 is a cross-sectional view illustrating a memory device 20 according to some example embodiments.

The memory device 20 may be same as or similar in some respects to the memory device 10 of FIG. 2, and therefore may be best understood with reference thereto where like numerals indicate like elements not described again in detail.

Referring to FIG. 12, the memory device 20 according to some example embodiments of the inventive concepts may include a memory cell having a vertical channel transistor structure.

The memory device 20 according to some example embodiments of the inventive concepts may include a first memory structure 100 and a second memory structure 200 arranged side by side in the first horizontal direction (X direction) and a transfer gate TG therebetween.

The first memory structure 100 positioned on one side (e.g., left side of the drawing) of the substrate 101 may include a first bit line BL1 extending in the first horizontal direction (X direction), a first vertical channel layer CH1 extending in the vertical direction (Z direction) on the first bit line BL1, a first source/drain region SD1 at vertically opposite ends of the first vertical channel layer CH1, a pair of first dielectric layers 110 extending in the vertical direction (Z direction) with the first vertical channel layer CH1 therebetween, a pair of first word lines WL1 facing each other with the first vertical channel layer CH1 and the pair of first dielectric layers 110 therebetween, a capacitor structure 140 positioned on the first vertical channel layer CH1 and the pair of first dielectric layers 110, and a first plate line PL1 positioned on the capacitor structure 140.

The second memory structure 200 positioned on the other side (e.g., right side of the drawing) of the substrate 101 may include a second bit line BL2 extending in the first horizontal direction (X direction), a second vertical channel layer CH2 extending in the vertical direction (Z direction) on the second bit line BL2, a second source/drain region SD2 at vertically opposite ends of the second vertical channel layer CH2, a pair of second dielectric layers 120 extending in the vertical direction (Z direction) with the second vertical channel layer CH2 therebetween, a pair of second word lines WL2 facing each other with the second vertical channel layer CH2 and the pair of second dielectric layers 120 therebetween, and a second plate line PL2 positioned on the second vertical channel layer CH2 and the pair of second dielectric layers 120.

In the memory device 20 according to some example embodiments of the inventive concepts, at least one of a pair of first dielectric layers 110 and a pair of second dielectric layers 120 includes a ferroelectric. In some example embodiments, the first memory structure 100 may constitute volatile memory, and the second memory structure 200 may constitute non-volatile memory.

In the memory device 20 according to some example embodiments of the inventive concepts, the first memory structure 100 or the second memory structure 200 may be selectively operated by using the transfer gate TG. Hereafter, the characteristics of the first memory structure 100 operating as volatile memory may be referred to as a ‘DRAM mode’, and the characteristics of the second memory structure 200 operating as non-volatile memory may be referred to as an ‘FeFET mode’.

In the memory device 20 according to some example embodiments of the inventive concepts, the first memory structure 100 may store data by using the capacitor structure 140, and the second memory structure 200 may store data by using polarization characteristics of the pair of second dielectric layers 120.

In the memory device 20 according to some example embodiments of the inventive concepts, the first bit line BL1 and the second bit line BL2 may be at the same vertical level, but may not be electrically connected to each other.

Operating principles of a programming operation and a sensing operation of the memory device 20 according to some example embodiments of the inventive concepts in each of the DRAM mode and the FeFET mode will be described below.

The memory device 20, according to some example embodiments of the inventive concepts, in which at least one of a pair of first dielectric layers and a pair of second dielectric layers 120 includes a ferroelectric may constitute hybrid memory that may selectively operate as volatile memory (e.g., the DRAM mode) or non-volatile memory (e.g., the FeFET mode) and may have a relatively higher integration and electrical reliability.

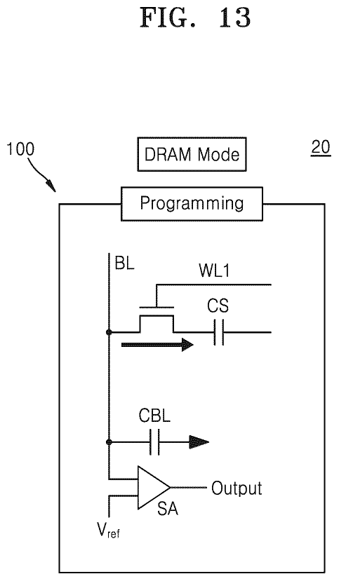

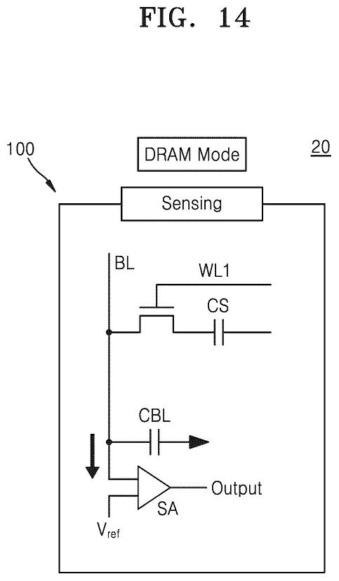

FIGS. 13 and 14 illustrate an operation of volatile memory in the memory device 20 illustrated in FIG. 12.

FIGS. 13 and 14 illustrate a programming operation and a sensing operation when the memory device 20 according to some example embodiments of the inventive concepts operates as volatile memory (e.g., a DRAM mode).

When the memory device 20 according to some example embodiments of the inventive concepts performs a programming operation (refer to FIG. 13) in the DRAM mode, a voltage may be applied to the first word line WL1 and the bit line BL to write data (for example, ‘0’ or ‘1’) in the cell capacitor CS.

In addition, when the memory device 20 according to some example embodiments of the inventive concepts performs a sensing operation (refer to FIG. 14) in the DRAM mode, the cell capacitor CS and a parasitic capacitor CBL perform a charge sharing operation, and data (for example, ‘0’ or ‘1’) may be read through a change in voltage level of the bit line BL.

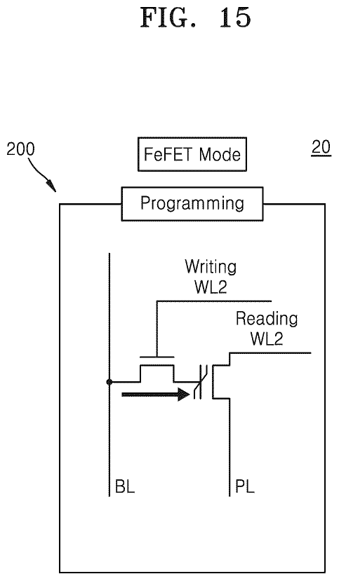

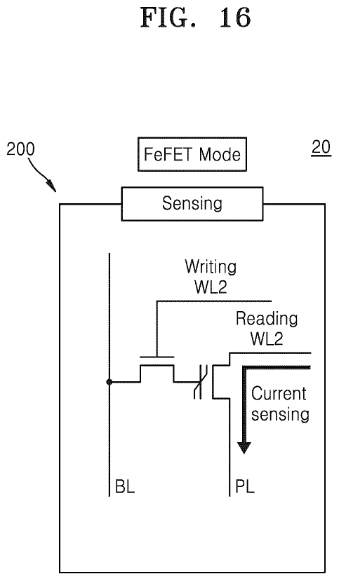

FIGS. 15 and 16 illustrate an operation of non-volatile memory in the memory device 20 illustrated in FIG. 12.

FIGS. 15 and 16 illustrate a programming operation and a sensing operation when the memory device 20 according to some example embodiments of the inventive concepts operates as non-volatile memory (e.g., an FeFET mode).

First, when the memory device 20 according to some example embodiments of the inventive concepts performs a programming operation (refer to FIG. 15) in the FeFET mode, by applying a voltage to a writing second word line Writing WL2, polarization may be induced in the second dielectric layer (dotted circle) to write data (for example, ‘0’ or ‘1’).

In addition, when the memory device 20 according to some example embodiments of the inventive concepts performs a sensing operation (refer to FIG. 16) in the FeFET mode, by applying a voltage to a reading second word line Reading WL2, a current flowing in the plating line PL may be sensed to read data (for example, ‘0’ or ‘1’).

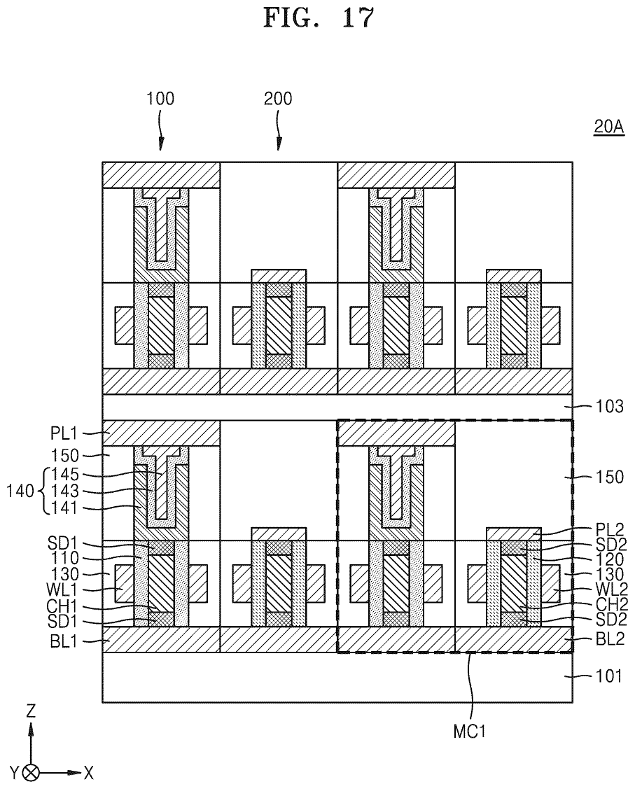

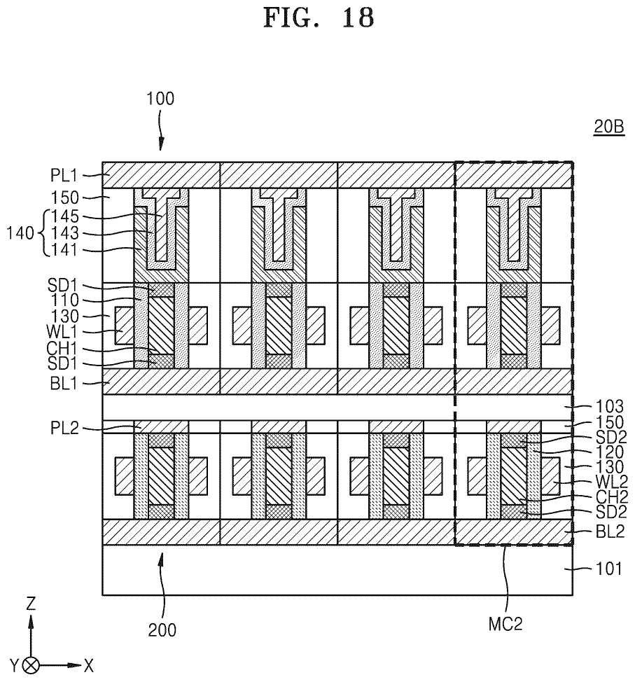

FIGS. 17 and 18 are cross-sectional views illustrating memory devices 20A and 20B, according to some example embodiments.

The memory devices 20A and 20B may be same as or similar in some respects to the memory device 10A of FIG. 11 and memory device 20 of FIG. 12, and therefore may be best understood with reference thereto where like numerals indicate like elements not described again in detail.

Referring to FIG. 17, the memory device 20A according to some example embodiments of the inventive concepts may include a plurality of first memory cells MC1 each having a vertical channel transistor structure in a stacked structure.

In the memory device 20A, according to some example embodiments of the inventive concepts, the first memory structure 100 and the second memory structure 200 arranged side by side in the first horizontal direction (X direction) are configured as one (or single) first memory cell MC1, and a plurality of first memory cells MC1 may be arranged in a lower portion and a plurality of first memory cells MC1 may be arranged in an upper portion.

Referring to FIG. 18, the memory device 20B according to some example embodiments of the inventive concepts may include a plurality of second memory cells MC2 each having a vertical channel transistor structure in a stacked structure.

In the memory device 20B, according to some example embodiments of the inventive concepts, the first memory structure 100 stacked on the second memory structure 200 in the vertical direction (Z direction) are configured as one (or single) second memory cell MC2, and the plurality of second memory cells MC2 may be arranged in the first horizontal direction (X direction).

In other words, in the memory device 20B, according to some example embodiments of the inventive concepts, a plurality of first memory structures 100 may be arranged in an upper portion in the first horizontal direction (X direction), and a plurality of second memory structures 200 may be arranged in a lower portion in the first horizontal direction (X direction).

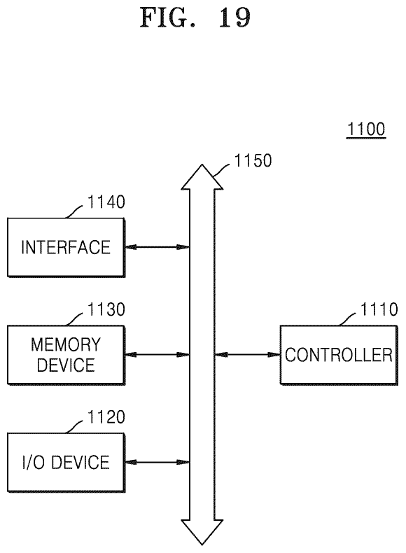

FIG. 19 is a block diagram illustrating a configuration of a system 1100 including a memory device according to some example embodiments.

Referring to FIG. 19, the system 1100 includes a controller 1110, an input/output device 1120, a memory device 1130, an interface 1140, and a bus 1150.

The system 1100 may be a mobile system or a system transmitting or receiving information. In some example embodiments, the mobile system may be a portable computer, a web tablet, a mobile phone, a digital music player, or a memory card.

The controller 1110 for controlling an execution program in the system 1100 may include a micro-processor, a digital signal processor, a micro-controller, or a similar device.

The input/output device 1120 may be used to input or output data of the system 1100. The system 1100 may be connected to an external device, for example, a personal computer (PC) or a network by using the input/output device 1120, and may exchange data with the external device. The input/output device 1120 may be, for example, a touch screen, a touch pad, a keyboard, or a display device.

The memory device 1130 may store data for an operation of the controller 1110 or may store data processed by the controller 1110. The memory device 1130 may include any one of the memory devices 10, 10A, 20, 20A, and 20B according to some example embodiments of the inventive concepts.

The interface 1140 may be or include a data transmission path between the system 1100 and the external device. The controller 1110, the input/output device 1120, the memory device 1130, and the interface 1140 may communicate with one another through the bus 1150.

As described herein, any devices, systems, modules, portions, units, controllers, circuits, and/or portions thereof according to any of the example embodiments, and/or any portions thereof (including, without limitation, the command decoder 1020, the address buffer 1030, the address decoder 1040, the control circuitry 1050, a sense amplifier (or a bit line sense amplifier (BLSA)) 1060, the data input/output circuitry 1070, the controller 1110, the input/output device 1120, the interface 1140, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A memory device comprising:
a bit line extending in a first horizontal direction;
a vertical channel layer extending in a vertical direction on the bit line;
a first dielectric layer and a second dielectric layer both extending in the vertical direction with the vertical channel layer therebetween;
a pair of word lines facing each other with the vertical channel layer, the first dielectric layer, and the second dielectric layer therebetween;
a plate line on the vertical channel layer, the first dielectric layer, and the second dielectric layer; and
a capacitor structure on the plate line, wherein at least one of the first dielectric layer or the second dielectric layer comprises a ferroelectric.

2. The memory device of claim 1, wherein the pair of word lines comprises:
a first word line contacting the first dielectric layer; and
a second word line contacting the second dielectric layer, and
wherein the bit line, the vertical channel layer, the first dielectric layer, the first word line, and the capacitor structure at least partially constitute volatile memory.

3. The memory device of claim 2, wherein the second dielectric layer comprises a ferroelectric, and
wherein the bit line, the vertical channel layer, the second dielectric layer, the second word line, and the plate line at least partially constitute non-volatile memory.

4. The memory device of claim 3, further comprising a sense amplifier connected to the bit line, wherein the volatile memory and the non-volatile memory share the sense amplifier.

5. The memory device of claim 4, wherein the volatile memory and the non-volatile memory are configured to be selectively operated based on a difference in voltages applied to the pair of word lines.

6. The memory device of claim 5, wherein the volatile memory stores data using the capacitor structure, and
wherein the non-volatile memory stores data using polarization characteristics of the second dielectric layer.

7. The memory device of claim 1, further comprising a first source/drain region at a lower end of the vertical channel layer and a second source/drain region at an upper end of the vertical channel layer, the lower end being opposite to the upper end in the vertical direction.

8. The memory device of claim 7, wherein each of the first and second dielectric layers extends from a lowermost end of the first source/drain region to an uppermost end of the second source/drain region in the vertical direction.

9. The memory device of claim 1, wherein the capacitor structure comprises a lower electrode, a capacitor dielectric layer, and an upper electrode, and
wherein the lower electrode contacts the plate line.

10. The memory device of claim 9, wherein a top surface of each of the first dielectric layer and the second dielectric layer is coplanar with a bottom surface of the plate line.

11. A memory device comprising:
a lower memory structure and an upper memory structure on the lower memory structure,
wherein the lower memory structure comprises,
a first bit line extending in a first horizontal direction;
a first vertical channel layer extending in a vertical direction on the first bit line;
a first dielectric layer and a second dielectric layer both extending in the vertical direction with the first vertical channel layer therebetween;
a first word line and a second word line facing each other with the first vertical channel layer, the first dielectric layer, and the second dielectric layer therebetween;
a first plate line on the first vertical channel layer, the first dielectric layer, and the second dielectric layer; and
a first capacitor structure on the first plate line, and
wherein the upper memory structure comprises,
a second bit line extending in the first horizontal direction;
a second vertical channel layer extending in the vertical direction on the second bit line;
a third dielectric layer and a fourth dielectric layer both extending in the vertical direction with the second vertical channel layer therebetween;
third and fourth word lines facing each other with the second vertical channel layer, the third dielectric layer, and the fourth dielectric layer therebetween;
a second plate line on the second vertical channel layer, the third dielectric layer, and the fourth dielectric layer; and
a second capacitor structure on the second plate line,
wherein at least one of the first dielectric layer or the second dielectric layer comprises a ferroelectric, and
wherein at least one of the third dielectric layer or the fourth dielectric layer comprises a ferroelectric.

12. The memory device of claim 11, further comprising:
the first word line contacting the first dielectric layer; and
the second word line contacting the second dielectric layer,
wherein the first bit line, the first vertical channel layer, the first dielectric layer, the first word line, and the first capacitor structure at least partially constitute first volatile memory, and
wherein the first bit line, the first vertical channel layer, the second dielectric layer, the second word line, and the first plate line at least partially constitute first non-volatile memory.

13. The memory device of claim 12, further comprising:
the third word line contacting the third dielectric layer; and
the fourth word line contacting the fourth dielectric layer,
wherein the second bit line, the second vertical channel layer, the third dielectric layer, the third word line, and the second capacitor structure at least partially constitute second volatile memory, and
wherein the second bit line, the second vertical channel layer, the fourth dielectric layer, the fourth word line, and the second plate line at least partially constitute second non-volatile memory.

14. The memory device of claim 13, wherein the first volatile memory and the first non-volatile memory are configured to be selectively operated based on a difference in voltages applied to the first and second word lines, and
wherein the second volatile memory and the second non-volatile memory are configured to be selectively operated based on a difference in voltages applied to the third and fourth word lines.

15. The memory device of claim 14, wherein each of the second and fourth dielectric layers comprises a ferroelectric,
wherein the first and second volatile memories are configured to store data using the first and second capacitor structures, and
wherein the first and second non-volatile memories are configured to store data using polarization characteristics of the second and fourth dielectric layers.

16. A memory device comprising:
a first memory structure and a second memory structure side by side in a first horizontal direction, wherein the first memory structure comprises:
a first bit line extending in the first horizontal direction;
a first vertical channel layer extending in a vertical direction on the first bit line;
a pair of first dielectric layers extending in the vertical direction with the first vertical channel layer therebetween;
a pair of first word lines facing each other with the first vertical channel layer and the pair of first dielectric layers therebetween; and
a capacitor structure on the first vertical channel layer and the pair of first dielectric layers,
wherein the second memory structure comprises:
a second bit line extending in the first horizontal direction;
a second vertical channel layer extending in the vertical direction on the second bit line;
a pair of second dielectric layers extending in the vertical direction with the second vertical channel layer therebetween;
a pair of second word lines facing each other with the second vertical channel layer and the pair of second dielectric layers therebetween; and
a plate line positioned on the second vertical channel layer and the pair of second dielectric layers, and
wherein at least one of the pair of first dielectric layers or the pair of second dielectric layers comprises a ferroelectric.

17. The memory device of claim 16, wherein the first memory structure at least partially constitutes volatile memory, and
wherein the second memory structure at least partially constitutes non-volatile memory.

18. The memory device of claim 17, further comprising a transfer gate, wherein the volatile memory and the non-volatile memory are selectively operated using the transfer gate.

19. The memory device of claim 18, wherein the volatile memory is configured to store data using the capacitor structure, and
wherein the non-volatile memory is configured to store data using polarization characteristics of the pair of second dielectric layers.

20. The memory device of claim 16, wherein the first bit line and the second bit line are at a same vertical level.
